(19) United States
(12) Patent Application Publication
(10) Pub. No.: US 2026/0123339 A1
(43) Pub. Date: Apr. 30, 2026

(54) APPARATUS FOR TREATING SUBSTRATE

(71) Applicant: SEMES CO., LTD., Cheonan-si (KR)

(72) Inventors: Hee Jun YOUN, Goyang-si (KR); Jun Hyun LIM, Seoul (KR); Gui Su PARK, Asan-si (KR); Eun Jung LEE, Seoul (KR); Jun Young CHOI, Cheongju-si (KR); Seul Gi CHOI, Busan (KR)

(73) Assignee: SEMES CO., LTD., Cheonan-si (KR)

(21) Appl. No.: 19/004,714

(22) Filed: Dec. 30, 2024

(30) Foreign Application Priority Data
Dec. 29, 2023 (KR) 10-2023-0196206

(51) Int. Cl. H01L 21/673; H01L 21/67

(52) U.S. Cl. CPC H10P 72/15; H10P 72/0416; H10P 72/0426

(57) ABSTRACT

The present invention provides an apparatus for treating a substrate. The apparatus of processing a substrate includes: a treatment bath having an receiving space accommodating treatment liquid, and treating a plurality of substrates; and a supporting unit supporting the substrates in the treatment bath, wherein the supporting unit includes: a support having a first supporting rod supporting end portions of the substrates in a vertical state; and a fixing plate coupled to the support and fixing the support, a plurality of first slots in which edges of the substrates are inserted is formed at the first supporting rod, each of the plurality of first slots is defined by a first side, a second side facing the first side, and a bottom, a front and a rear of the first slot are open toward the receiving space, and the bottom of the first slot comprises contact protrusions protruding upward from a lower end of the first side of the first slot and supporting lower end portions of the substrates.

### CROSS-REFERENCE TO RELATED APPLICATIONS

This application claims priority to and the benefit of Korean Patent Application No. 10-2023-0196206 filed in the Korean Intellectual Property Office on Dec. 29, 2023, the entire contents of which are incorporated herein by reference.

### TECHNICAL FIELD

The present invention relates to an apparatus of processing a substrate and, in more detail, an apparatus of processing a substrate that treats a substrate by immersing the substrate into treatment liquid.

### BACKGROUND ART

In order to manufacture a semiconductor device, a desired pattern is formed on a substrate such as a wafer through various processes such as photographing, etching, ashing, ion injection, and thin film deposition. Various treatment liquids and treatment gases are used in each of the processes, and particles and process byproducts are produced during the processes. A liquid treatment process is performed on a substrate before and after each process to remove a thin film, particles, and process byproducts on the substrate from the substrate. In general, a liquid treatment process treats a substrate with a chemical, and then removes the chemical on the substrate with a rinse solution and then performs drying treatment.

As a method of treating a substrate with treatment liquid such as a chemical and/or a rinse solution, there is a batch-type treatment method that treats a plurality of substrates in a vertical posture in batch. The batch-type treatment method performs substrate treatment by immersing a plurality of substrates in a vertical posture in batch into a treatment bath in which a chemical or a rinse solution is stored. Substrates are supported by a supporting unit having slots in which substrates are inserted, and immersed into a treatment bath in this state. There is a problem that while substrates are treated in a treatment bath storing a chemical or a rinse solution, the chemical or the rinse solution does not smoothly flow around the portions where the substrates are supported by a supporting unit, that is, the contact portions between slots and the substrates. Accordingly, treatment of substrates by a chemical and washing of substrates by a rinse solution are not carried out smoothly and the substrate treatment efficiency decreases. In particular, when substrates are treated with a high-temperature chemical, a temperature difference may increase around the contact portions of the substrates and a supporting unit and the temperature distribution of the substrates may become non-uniform.

### SUMMARY OF THE INVENTION

An objective of the present invention is to provide an apparatus of processing a substrate that can efficiently perform liquid treatment on substrates.

An objective of the present invention is to provide an apparatus of processing a substrate in which uniform temperature distribution of substrates can be achieved when the substrates are treated with high-temperature treatment liquid.

An objective of the present invention is to provide an apparatus of processing a substrate in which treatment liquid can smoothly flow when substrates are treated in a treatment bath storing the treatment liquid.

An objective of the present invention is to provide an apparatus of processing a substrate in which treatment liquid can smoothly flow around the contact portions between substrates and a supporting unit when the substrates are treated in a treatment bath storing the treatment liquid.

The objectives of the present invention are not limited thereto and other objectives not stated herein may be clearly understood by those skilled in the art from the following description.

The present invention provides an apparatus for treating a substrate. The apparatus of processing a substrate includes: a treatment bath having a receiving space accommodating treatment liquid, and treating a plurality of substrates; and a supporting unit supporting the substrates in the treatment bath, wherein the supporting unit includes: a support having a first supporting rod supporting end portions of the substrates in a vertical state; and a fixing plate coupled to the support and fixing the support, a plurality of first slots in which edges of the substrates are inserted is formed at the first supporting rod, each of the plurality of first slots is defined by a first side, a second side facing the first side, and a bottom, a front and a rear of the first slot may be open toward the receiving space, and the bottom of the first slot comprises contact protrusions protruding upward from a lower end of the first side of the first slot and supporting lower end portions of the substrates.

In an embodiment, the first side of the first slot and the second side of the first slot may be provided such that a distance between the first side and the second side decreases downward.

In an embodiment, the first side and the second side may be inclined.

In an embodiment, the first side and the second side of the first slot each may have: a first region extending upward from the bottom; a second region extending upward from the first region; and a third region extending upward from the second region, the first region of the first side and the first region of the second side may be disposed to face each other, the second region of the first side and the second region of the second side may be disposed to face each other, the third region of the first side and the third region of the second side may be disposed to face each other, the second region of the first side and the second region of the second side may be inclined surfaces, and a distance between the second region of the first side and the second region of the second side may be smaller than the third region of the first side and the third region of the second side.

In an embodiment, the first side and the second side of the first slot each may be provided such that a width of the surface increases downward.

In an embodiment, the contact protrusion may have a top, a first side, and a second side, the top of the contact protrusion may be a flat surface, and the top of the contact protrusion may support a lower end portion of the substrate when the first supporting rod supports the substrate.

In an embodiment, both sides of the contact protrusion each may be inclined.

In an embodiment, the top of the contact protrusion may be provided at the same height as an upper end of the first region of the first side of the first slot.

In an embodiment, a width of the top of the contact protrusion in a direction parallel with an arrangement direction of the first slots may be the same as a thickness of the substrate.

In an embodiment, the support may further include a second supporting rod supporting end portions of the substrates in a vertical state, and a plurality of second slots in which edges of the substrates are inserted may be formed at the second supporting rod.

In an embodiment, the second supporting rod may include a top, a first side, and a second side, the top of the second supporting rod comprises a first height portion and a second height portion lower than the first height portion, the second slot is formed at the first height portion, and the second slot may be formed at a position higher than the second height portion.

In an embodiment, a distance from a center of the substrate to the second supporting rod may be larger than a distance from the center of the substrate to the first supporting rod when seen from above.

In an embodiment, the apparatus may further include a transfer robot coupled to an upper end of the fixing plate, wherein the transfer robot may immerse or unload the supporting unit and the substrates supported on the supporting unit into or out of the treatment liquid by moving up or down the supporting unit.

Further, the present invention provides an apparatus for treating a substrate. In an embodiment, the apparatus of processing a substrate includes: a treatment bath having a receiving space accommodating treatment liquid, and treating a plurality of substrates; and a supporting unit supporting the substrates in the treatment bath, wherein the supporting unit includes: a support having a first supporting rod and a second supporting rod supporting end portions of the substrates in a vertical state; and a fixing plate coupled to the support and fixing the support, a plurality of first slots in which edges of the substrates are inserted is formed at the first supporting rod, a plurality of second slots in which edges of the substrates are inserted is formed at the second supporting rod, the second supporting rod includes a top, a first side, and a second side, the top of the second supporting rod comprises a first height portion and a second height portion lower than the first height portion, the second slot is formed at the first height portion, and the second slot may be formed at a position higher than the second height portion.

In an embodiment, each of the plurality of first slots may be defined by a first side, a second side facing the first side, and a bottom, a front and a rear of the first slot may be open toward the receiving space, and the bottom of the first slot may include contact protrusions protruding upward from a lower end of the first side of the first slot and supporting lower end portions of the substrates.

In an embodiment, the first side of the first slot and the second side of the first slot may be inclined such that a distance between the first side and the second side decreases downward.

In an embodiment, the first side and the second side of the first slot each may have: a first region extending upward from the bottom; a second region extending upward from the first region; and a third region extending upward from the second region, the first region of the first side and the first region of the second side may be disposed to face each other, the second region of the first side and the second region of the second side may be disposed to face each other, the third region of the first side and the third region of the second side may be disposed to face each other, the second region of the first side and the second region of the second side may be inclined surfaces, and a distance between the second region of the first side and the second region of the second side may be smaller than the third region of the first side and the third region of the second side.

In an embodiment, the contact protrusion may have a top and sides, the top of the contact protrusion may be a flat surface, and the top of the contact protrusion may support a lower end portion of the substrate when the first supporting rod supports the substrate.

In an embodiment, the top of the contact protrusion may be provided at the same height as an upper end of the first region of the first side of the first slot.

Further, the present invention provides an apparatus for treating a substrate. In an embodiment, the apparatus of processing a substrate includes: a treatment bath having a receiving space accommodating treatment liquid, and treating a plurality of substrates; and a supporting unit supporting the substrates in the treatment bath,
wherein the supporting unit includes: a support having a first supporting rod and a second supporting rod supporting end portions of the substrates in a vertical state; a fixing plate coupled to the support and fixing the support; and a transfer robot coupled to an upper end of the fixing plate, a plurality of first slots in which edges of the substrates are inserted is formed at the first supporting rod, a plurality of second slots in which edges of the substrates are inserted is formed at the second supporting rod, each of the plurality of first slots is defined by a first side, a second side facing the first side, and a bottom, a front and a rear of the first slot may be open toward the receiving space, and the bottom of the first slot comprises contact protrusions protruding upward from a lower end of the first side of the first slot and supporting lower end portions of the substrates, the second supporting rod includes a top, a first side, and a second side, the top of the second supporting rod comprises a first height portion and a second height portion lower than the first height portion, the second slot is formed at the first height portion, the second slot is formed at a position higher than the second height portion, and a distance from a center of the substrate to the second supporting rod is larger than a distance from the center of the substrate to the first supporting rod when seen from above.

According to an embodiment, it is possible to efficiently perform liquid treatment on substrates.

Further, according to an embodiment of the present invention, it is possible to make temperature distribution of substrates uniform when treating the substrates with high-temperature treatment liquid.

Further, according to an embodiment of the present invention, treatment liquid can smoothly flow when substrates are treated in the treatment bath storing the treatment liquid.

Further, according to an embodiment of the present invention, treatment liquid can smoothly flow around the contact portions of substrates and the supporting unit when the substrates are treated in the treatment bath storing the treatment liquid.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a schematic view of an apparatus of processing a substrate according to an embodiment of the present invention seen from above.

FIG. 2 is a view schematically showing the structure of the second chemical liquid bath of FIG. 1.

FIG. 3 is a perspective view showing an embodiment of the supporting unit of FIG. 2.

FIG. 4 is a detailed enlarged view of the first supporting rod of FIG. 3.

FIG. 5 is a detailed view showing the first supporting rod of FIG. 3 in a direction perpendicular to the longitudinal direction of the first supporting rod.

FIG. 6 is a cross-sectional view showing the first supporting rod of FIG. 3 in a direction parallel with the longitudinal direction of the first supporting rod.

FIG. 7 is a detailed view showing the appearance when a substrate is inserted in a first slot of the first supporting rod of FIG. 3.

FIG. 8 is a view showing another embodiment of a contact protrusion formed on the bottom of the first slot.

FIG. 9 is a detailed view showing the second supporting rod of FIG. 3 in a direction parallel with the longitudinal direction of the second supporting rod.

FIG. 10 shows the second chemical liquid bath of FIG. 1 in which a supporting unit according to another embodiment of the present invention is installed.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Further, components that transfer substrates W to be described below, for example, transfer units or transfer robots may be referred to as transfer modules.

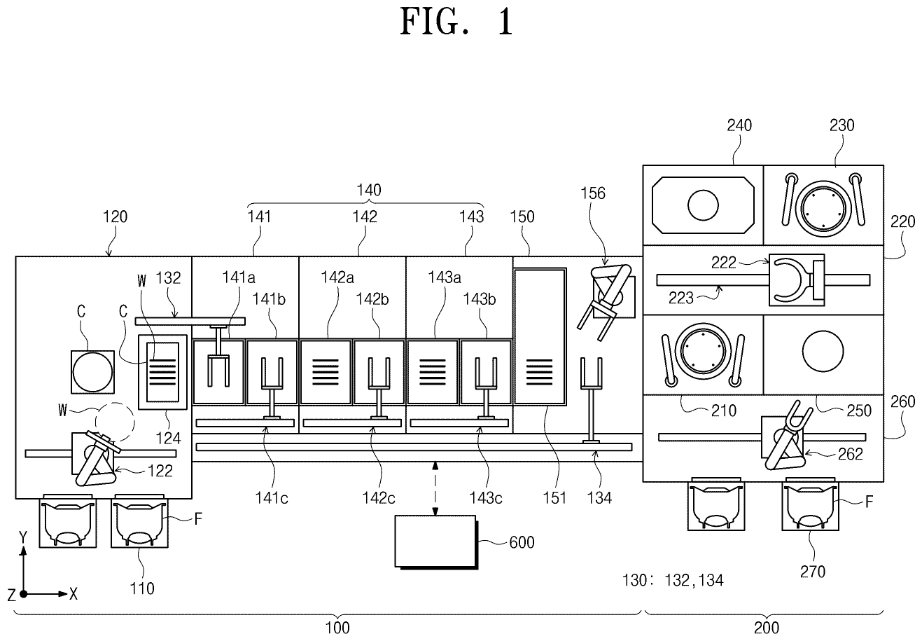

Hereafter, embodiments of the present invention are described with reference to FIG. 1 to FIG. 10.

FIG. 1 is a schematic view of an apparatus of processing a substrate according to an embodiment of the present invention seen from above.

Referring to FIG. 1, an apparatus 10 for treating a substrate may include a first process performing unit 100, a second process performing unit 200, and a control unit 600. The first process performing unit 100 and the second process performing unit 200 may be arranged in a line when seen from above. Hereafter, the direction in which the first process performing unit 100 and the second process performing unit 200 are arranged is referred to as a first direction X, a direction perpendicular to the first direction X when seen from above is referred to as a second direction Y, and a direction perpendicular to the first direction X and the second direction Y is referred to as a third direction Z.

The first process performing unit 100 can perform liquid treatment on a plurality of substrates W all at once in a batch type. For example, liquid treatment may be washing treatment that removes unnecessary films or particles on the substrates W. The first process performing unit 100 can simultaneously treat a plurality of substrates W with a pattern surface of the substrates W positioned in a direction perpendicular to the ground.

The first process performing unit 100 may include a first load port unit 110, an index chamber 120, a transfer unit 130, a liquid treatment chamber, and a posture changing unit 150.

The first load port unit 110 may include at least one or more load ports. A conveying container F in which a substrate W is accommodated may be placed in the load ports of the first load port unit 110. A plurality of substrates W may be accommodated in the conveying container F. For example, 25 sheets of substrates W may be accommodated in the conveying container F. The conveying container F may be a cassette, a FOD, or a FOUP. The conveying container F can be loaded into the first load port unit 110 by a container transfer device. The substrates W accommodated in the conveying container F that is placed in the first load port unit 110 may be non-treated substrates W. The non-treated substrates W, for example, may be substrates W that have not been treated or substrates W that have been partially treated but require liquid treatment.

Further, a container F in which non-treated substrates W are accommodated can be placed in the first load port unit 110. That is, the first load port unit 110 can serve to load substrates W that require treatment.

The first load port unit 110 may be coupled to the index chamber 120. The index chamber 120 and the first load port unit 110 may be arranged in the second direction Y. The first index chamber 120 may include an index robot 122 and a posture changing unit 124. The index robot 122 can unload substrates W that have not been treated or require treatment out of the container F seated in the first load port unit 110. The first transfer robot 122 can unload substrates W from the container F and load the substrates W into an accommodation container C provided in the first index chamber 120. The first transfer robot 122 may have a batch hand that can simultaneously hold and transfer a plurality of sheets (e.g. 25 sheets) of substrates W.

The accommodation container C may have a substantially box shape. The accommodation container C may have a receiving space therein. A plurality of substrates W may be accommodated in the receiving space of the accommodation container C. For example, 50 sheets of substrates W may be accommodated in the receiving space of the accommodation container C. The accommodation container C may have a box shape of which at least two or more surfaces of the surfaces thereof are open. A supporting member that supports/holds substrates W may be provided in the receiving space of the accommodation container C.

When substrates W unloaded from the conveying container F finish being loaded into the accommodation container C, the substrates W can be transferred to the posture changing unit 124 disposed in the index chamber 120 by a transfer part not shown. The posture changing unit 124 can rotate the accommodation container C. For example, the posture changing unit 124 can rotate the accommodation container C such that an open portion of the accommodation container C faces up. When the accommodation container C is rotated such that an open portion faces up, the posture of the substrates W accommodated in the accommodation container C can be changed from a horizontal posture to a vertical posture. The horizontal posture may mean that the upper surface of a substrate (for example, a surface having a pattern formed thereon) is parallel with an X-Y plane (i.e., the ground) and the vertical position may mean that the upper surface of a substrate W is parallel with an X-Z plane or a Y-Z plane (i.e., a surface perpendicular to the ground).

The transfer unit 130 may include a first transfer unit 132 transferring substrates W between the index chamber 120 and a batch treatment unit 140 and a second transfer unit 134 transferring substrates W between the batch treatment unit 140 and the posture changing unit 150 to be described below.

The first transfer unit 132 may include a rail extending in the first direction X and a hand configured to be able to transfer a plurality of substrates W at a time. The first transfer unit 132 can hold substrates W with the posture changed in the posture changing unit 124 and transfer the held substrates W to a liquid treatment chamber. For example, the first transfer unit 132 can transfer substrates W with the posture changed at the posture changing unit 124 to any one treatment bath selected from batch treatment baths 141a to 143b of the batch treatment unit 140. The second transfer unit 134 may include a rail extending in the first direction X and a hand configured to be able to transfer a plurality of substrates W at a time.

The second transfer unit 134 may be configured to be able to transfer substrates W between a first batch treatment unit 141, a second batch treatment unit 142, and a third batch treatment unit 143 of the batch treatment unit 140 to be described below. Further, the second transfer unit 134 may be configured to be able to transfer substrates W between the batch treatment unit 140 and the posture changing unit 150.

The liquid treatment chamber performs liquid treatment on substrates W by supplying treatment liquid to the substrates W.

According to an example, the liquid treatment chamber is provided as the batch treatment unit 140 that performs liquid treatment on a plurality of substrates W at a time. Liquid treatment can be performed on a plurality of substrates W at a time using treatment liquid in the batch treatment unit 140. The treatment liquid that is used in the batch treatment unit 140 may be a chemical and/or a rinse solution. For example, the chemical may be a chemical that has the property of strong acid or strong base. For example, the chemical may be appropriately selected from an Ammonia-Hydrogen Peroxide Mixture (APM), a Hydrochloricacid-Hydrogen Peroxide Mixture (HPM), a Hydrofluoricacid-Hydrogen Peroxide Mixture (FPM), Diluted Hydrofluoric acid (DHF), Diluted Sulfuric acid Peroxide (DSP), a chemical removing SiN, a chemical containing phosphoric acid, a chemical containing sulfuric acid, or the like. The rinse solution may be water. For example, the rinse solution may be pure water.

The batch treatment unit 140 may include a first batch treatment unit 141, a second batch treatment unit 142, and a third batch treatment unit 143.

The first batch treatment unit 141, the second batch treatment unit 142, and the third batch treatment unit 143 each include a chemical liquid bath, a rinse bath, and a batch transfer unit transferring substrates W between them.

In each batch treatment unit, substrates W are treated with first treatment liquid in the chemical liquid bath and then treated with second treatment liquid in the rinse bath. The first treatment liquid may be a chemical and the second treatment liquid may be a rinse solution.

Substrates W changed in posture by the posture changing unit 124 and accommodated in the accommodation container C and substrates W accommodated in the batch treatment bath of the batch treatment unit 140 may be arranged in parallel in the second direction Y when seen from above.

Further, substrates W accommodated in the batch treatment baths 141a to 143b of the batch treatment unit 140 and substrates W accommodated in a posture changing bath 151 of the posture changing unit 150 may be arranged in parallel in the second direction Y when seen from above.

The first batch treatment unit 141 may include a first chemical liquid bath 141a, a first rinse bath 141b, and a first batch transfer unit 141c.

It is possible to simultaneously perform liquid treatment on a plurality of substrates W with a chemical such as DHF in the first chemical liquid bath 141a. It is possible to simultaneously perform liquid treatment on a plurality of substrates W with a rinse solution in the first rinse bath 141b. However, the present invention is not limited thereto and the treatment liquid that is used in the first chemical liquid bath 141a may be variously changed to treatment liquid selected from the treatment liquids described above.

Thin films on substrates W, remaining membrane materials on the substrates W, foreign substances on the substrates W, or the like can be removed in the first chemical liquid bath 141a. It is possible to simultaneously treat a plurality of substrates W with a rinse solution such as pure water in the first rinse bath 141b. A chemical remaining on substrates W after used to treat the substrates W in the first chemical liquid bath 141a is removed from the substrates W in the first rinse bath 141b.

The first batch transfer unit 141c may be configured to be able to transfer substrates W between the first chemical liquid bath 141a and the first rinse bath 141b.

The second batch treatment unit 142 may include a second chemical liquid bath 142a, a second rinse bath 142b, and a second batch transfer unit 142c.

It is possible to simultaneously perform liquid treatment on a plurality of substrates W with a chemical containing phosphoric acid in the second chemical liquid bath 142a. It is possible to simultaneously treat a plurality of substrates W with a rinse solution in the second rinse bath 142b. However, the present invention is not limited thereto and the treatment liquid that is used in the second chemical liquid bath 142a may be variously changed to treatment liquid selected from the treatment liquids described above.

The second batch transfer unit 142c may be configured to be able to transfer substrates W between the second chemical liquid bath 142a and the second rinse bath 142b.

The third batch treatment unit 143 may include a third chemical liquid bath 143a, a third rinse bath 143b, and a third batch transfer unit 143c.

It is possible to simultaneously perform liquid treatment on a plurality of substrates W with a chemical containing phosphoric acid in the third chemical liquid bath 143a. It is possible to simultaneously treat a plurality of substrates W with a rinse solution in the third rinse bath 143b. However, the present invention is not limited thereto and the treatment liquid that is used in the third chemical liquid bath 143a may be variously changed to treatment liquid selected from the treatment liquids described above.

The third batch transfer unit 143c may be configured to be able to transfer substrates W between the third chemical liquid bath 143a and the third rinse bath 143b.

According to an embodiment, the second batch treatment unit 142 and the third batch treatment unit 143 can treat substrates W with the same chemical and the first batch treatment unit 141 can treat substrates W with a chemical different from that of the second batch treatment unit 142 or the third batch treatment unit 143. Hereafter, it is exemplarily described that the second batch treatment unit 142 and the third batch treatment unit 143 treat substrates W with a phosphoric acid solution and the first batch treatment unit 141 treats substrates W with any one chemical of the chemicals exemplified above.

It is shown in FIG. 1 that the batch treatment unit 140 includes the first batch treatment unit 141, the second batch treatment unit 142, and the third batch treatment unit 143, but the present invention is not limited thereto.

For example, additional batch treatment units may be further provided. Additional batch treatment units can treat substrates W with a chemical the same as or different from that of the first disposition treatment unit 141, the second disposition treatment unit 142, or the third batch treatment unit 143.

Selectively, the batch treatment unit 140 may include only the second batch treatment unit 142 and the third batch treatment unit 143 without the first batch treatment unit 141.

Selectively, the batch treatment unit 140 may include only the second batch treatment unit 142.

Hereafter, the structure of the batch treatment unit 140 is described.

The first batch treatment unit 141, the second batch treatment unit 142, and the third batch treatment unit 143 are provided in the same or similar structures. The following describes the second batch treatment unit 142 as the main focus.

The second batch treatment unit 142 may include a second chemical liquid bath 142a, a second rinse bath 142b, and a second batch transfer unit 142c.

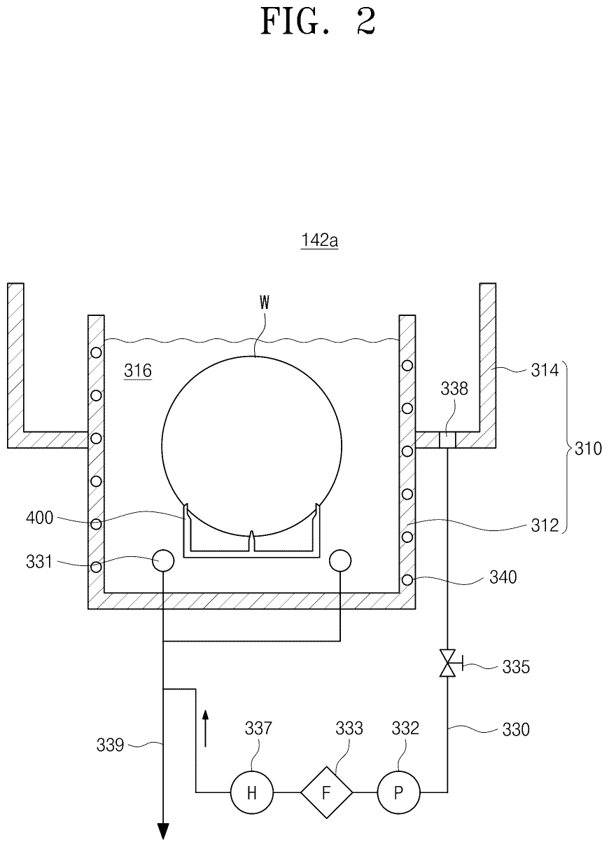

FIG. 2 is a view schematically showing the structure of the second chemical liquid bath of FIG. 1.

The second chemical liquid bath 142a has a circulation line 330, a heating unit 340, and a supporting unit 400.

The treatment bath 310 may have an inner bath 312 and an outer bath 314. The inner bath 312 has a receiving space 316 therein. The inner bath 312 may have a box shape with open top. For example, the inner bath 312 may have a rectangular prism shape. Treatment liquid may be accommodated in the receiving space 316. The treatment liquid may be a phosphoric acid solution.

The outer bath 314 is provided to surround the inner bath 312 outside the inner bath 312. For example, the outer bath 314 has a rectangular prism shape similar to the inner bath 312. The outer bath 314 is provided in a size larger than the inner bath 312. The outer bath 314 accommodates treatment liquid overflowing from the inner bath 312. A discharge hole 338 for discharging treatment liquid is formed at the outer bath 314. The discharge hole 338 is formed through the bottom of the outer bath 314. Treatment liquid overflowing from the inner bath 312 to the outer bath 314 is discharged to the circulation line 330 to be described below through the discharge hole 338.

The circulation line 330 circulates treatment liquid in the treatment bath 310. The circulation line 330 performs a series of treatment liquid circulation process of supplying treatment liquid to the treatment bath 310, filtering the treatment liquid discharged from the treatment bath 310, and resupplying or draining the treatment liquid.

A liquid supply pipe 331, a pump 332, a filter 333, a valve 335, and a heater 337 are installed in the circulation line 330. The pump 332 provides dynamic pressure to treatment liquid such that treatment liquid circulates along the circulation line 330.

The liquid supply pipe 331 supplies treatment liquid to the treatment bath 310. A portion of the liquid supply pipe 331 is disposed in the treatment bath 310. A portion of the liquid supply pipe 331 is disposed at a lower portion of the receiving space 316 of the inner bath 312.

A plurality of liquid supply pipes 331 may be provided. In this case, the liquid supply pipes 331 may be disposed in parallel with each other. The liquid supply pipes 331 are positioned lower than a substrate W that is treated in the receiving space 316. The liquid supply pipes 331 may be positioned lower than the supporting unit 400.

The filter 333 removes foreign substances in treatment liquid circulating in the circulation line 330.

The valve 335 opens and closes the circulation line 330. When the valve 335 is opened, treatment liquid in the treatment bath 310 keeps circulating along the circulation line 330.

The heater 337 can heat treatment liquid that is supplied to the treatment bath 310 to a set temperature.

The heating unit 340 can heat the treatment liquid accommodated in the receiving space 316. The heating unit 340 may be disposed at a side of the inner bath 312. The heating unit 340 may be embedded in the wall of the inner bath 312 or may be disposed in a housing of the treatment bath 310 not shown.

The supporting unit 400 can support a substrate M. The supporting unit 400 can support substrates W in the receiving space 316. The supporting unit 400 may be configured to be able to support a plurality of substrates W. For example, the supporting unit 400 may be configured to be able to support 50 sheets of substrates W. The supporting unit 400 may be a lifter coupled to the second batch transfer unit 142c to be described below and configured to be able to transfer substrates W between the second chemical liquid bath 142a and the second rinse bath 142b. The supporting unit 400 is described below.

The second rinse bath 142b may have a structure similar to the second chemical liquid bath 142a. For example, the second rinse bath 142b also includes a treatment bath 310 having a receiving space 316 and treatment liquid can be accommodated in the receiving space 316. The treatment liquid may be a rinse solution.

The second rinse bath 142b, unlike the second chemical liquid bath 142a, includes the treatment bath 310 having the receiving space 316 and may be composed of only an inner bath 312 without an outer bath 314.

The second batch transfer unit 142c may be configured to be able to transfer substrates W between the second chemical liquid bath 142a and the second rinse bath 142b. The second batch transfer unit 142c may be configured to be able to transfer the supporting unit 400 to be described below between the second chemical liquid bath 142a and the second rinse bath 142b.

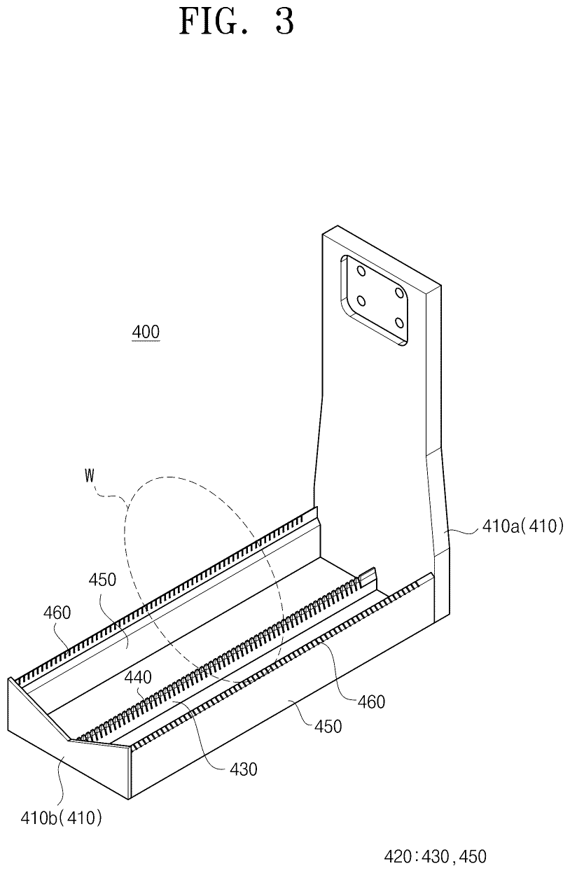

Hereafter, an embodiment of the supporting unit of FIG. 2 is described with reference to FIG. 3 to FIG. 9.

FIG. 3 is a perspective view showing an embodiment of the supporting unit of FIG. 2.

Referring to FIG. 3, the supporting unit 400 includes a fixing plate 410 and a support 420.

The fixing plate 410 is coupled to the support 420 and fixes the support 420.

The support 420 supports substrates W. The support 420 may include a plurality of supporting rods so that substrates W can be stably supported.

The support 420 of the supporting unit 400 shown in FIG. 3 may include a first supporting rod 430 and a second supporting rod 450. The second supporting rod 450 may be provided outside the first supporting rod 430. The first supporting rod 430 may be provided to be able to support the center of the lower portion of the end portion of a substrate W, that is, the lower end portion of the substrate W when the supporting unit 400 supports the substrate W. Two second supporting rods 450 may be provided at both sides of first supporting rod 430, respectively. When a substrate W is supported on the supporting unit 400, the distance from the center of the substrate W to the second supporting rod 450 when seen from above may be larger than the distance from the center of the substrate W to the first supporting rod 430.

The first supporting rod 430 and the second supporting rod 450 each have a bar shape. Two second supporting rods 450 are disposed to be spaced apart from each other at the same height.

The first supporting rod 430 and the second supporting rods 450 support the end portion of a substrate W. Hereafter, the end portion of a substrate W includes the side ends and the lower end of the substrate W vertically erected and the region between the side end and the lower end.

A plurality of slots is formed with predetermined gaps therebetween at the upper end of each of the first supporting rod 430 and the second supporting rods 450 in the longitudinal direction of the first supporting rod 430 and the second supporting rods 450. A plurality of first slots 440 in which the edges of substrates W are inserted is formed at the upper end of the first supporting rod 430 and a plurality of second slots 460 in which the edges of substrates W are inserted is formed at the upper ends of the second supporting rods 450. The first slots 440 and the second slots 460 are formed in the number corresponding to the number of substrates w. For example, twenty five or fifty first slots 440 and second slots 460 may be formed.

The fixing plate 410 fixes the first supporting rod 430 and the second supporting rods 450 of the supporting unit 420. Two fixing plates 410 are provided at both ends of the supporting unit 420. First ends of the first supporting rod 430 and the second supporting rods 450 are coupled to a first fixing plate 410a. Second ends of the first supporting rod 430 and the second supporting rods 450 are coupled to a second fixing plate 410b.

The first fixing plate 410a may be configured to be able to transfer substrates W between the second chemical liquid bath 142a and the second rinse bath 142b by being coupled to the second batch transfer unit 142c to be described below.

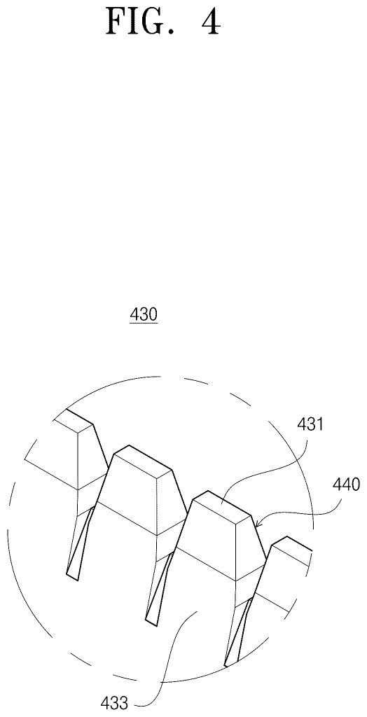

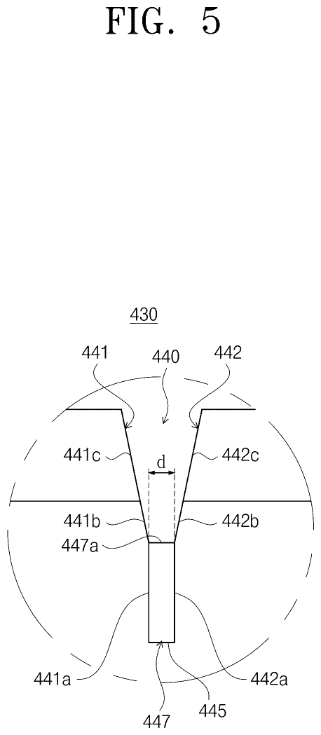

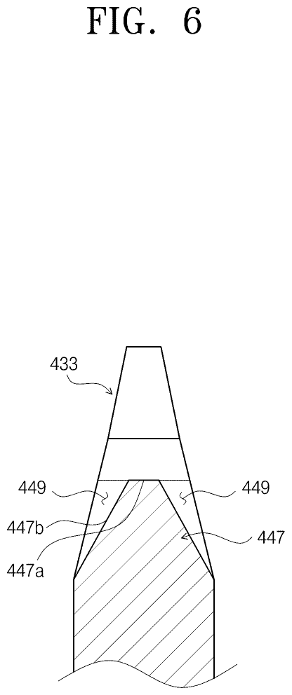

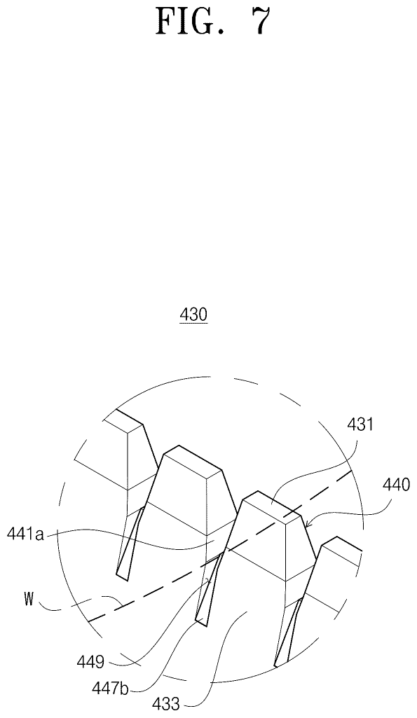

FIG. 4 is a detailed enlarged view of the first supporting rod of FIG. 3, FIG. 5 is a detailed view showing the first supporting rod of FIG. 3 in a direction perpendicular to the longitudinal direction of the first supporting rod, and FIG. 6 is a cross-sectional view showing the first supporting rod of FIG. 3 in a direction parallel with the longitudinal direction of the first supporting rod. FIG. 7 is a detailed view showing the appearance when a substrate is inserted in a first slot of the first supporting rod of FIG. 3.

Hereafter, the first supporting rod 430 and the first slots 440 are described in detail with reference to FIG. 3 to FIG. 7.

The first supporting rod 430 includes a top 431 and sides 433. The distance between the two sides 433 of the first supporting rod 430 is defined as the thickness of the first supporting rod 430. The thickness of the first supporting rod 430 may decrease upward. For example, the sides 433 of the first supporting rod 430 may become thin as they go close to the top 431. The sides 433 of the first supporting rod 430 may be inclined.

The top 431 of the first supporting rod 430 may be flat. The top 431 of the first supporting rod 430 may a rectangle.

The first supporting rod 430, as described above, a plurality of first slots 440 spaced apart from each other in the longitudinal direction of the first supporting rod 430. The first slot 440 is defined by a first side 441, a second side 443, and a bottom 445. That is, the first slot 440 may be defined as the space between the first side 441, the second side 443, and the bottom 445 on the first support rod 430. The front and rear of the first slot 440, that is, the directions of the sides 433 of the first supporting rod 430 are open toward the receiving space 316.

The distance between the first side 441 and the second side 443 may decrease downward. Accordingly, the width of the first slot 440 may decrease downward. The first side 441 and the second side 443 each may be inclined. The first side 441 and the second side 443 each may be inclined to be perpendicular to the bottom 445 in a partial region.

As shown in FIG. 5, the first side 441 and the second side 443 each may be divided into a plurality of regions. For example, the first side 441 may have a first region 441a being in contact with the bottom 445 and extending from the bottom 445, a second region 441b connected with the first region 441a and extending upward from the first region 441a, and a third region 441c connected with the second region 441b and extending upward from the second region 441b. Further, the second side 443 may have a first region 443a being in contact with the bottom, a second region 443b connected with the first region 443a and provided over the first region 443a, and a third region 443c connected with the second region 443b and provided over the second region 443b.

The first regions 441a and 443a to the third regions 441c and 443c of the first side 441 and the second side 443 each may be inclined. Alternatively, the first regions 441a and 443a to the second regions 441b and 443b of the first side 441 and the second side 443 each may be inclined, and the third regions 441c and 443c may be perpendicular to the bottom 445. The inclinations of the first regions 441a and 443a to the third regions 441c and 443c of the first side 441 and the second side 443 may be different from each other.

The bottom 445 is a flat surface. Contact protrusions 447 protruding upward are formed on the bottom 445.

The contact protrusion 447, as shown in FIG. 6, has a top 447a and sides 447b.

The top 447a may be a flat surface. The top 447a shown in FIG. 6 may be parallel with the bottom 445 of the first slot 440. When a substrate W is inserted in the first slot 440, the top 447a supports the end portion of the substrate W. The top 447a can support the lower end portion of the substrate W. The top 447a may be positioned at the same height of the boundary between the first region 441a, 443a and the second region 441b, 443b of the first side 441 or the second side 443 of the first slot 440 described above. That is, the top 447a of the contact protrusion 447 may be positioned at the same height as the upper end of the first region 441a, 443a of the first side 441 or the second side 443.

The width of the top 447a in the same direction as the arrangement direction of the slots 440 may be the same as the thickness of a substrate W. Accordingly, when a substrate W is inserted in the first slot 440, the top 447a can stably support the end portion of the substrate W.

The sides 447b of the contact protrusion 447 inclined such that the distance between the sides 447b increases downward. Accordingly, as shown in FIG. 7, when a substrate W is inserted in the first slot 440, the top 447a of the contact protrusion 447 supports the end portion of the substrate W and a predetermined space is formed between the substrate W, the sides 447b of the supporting protrusion 447, and the first regions 441a and 443a of the first side 441 and the second side 443. This is defined as a first flow space 449.

The first flow space 449 is positioned under the supporting surface that supports the end portion of a substrate W in contact with the end portion of the substrate W, that is, the top 447a of the contact protrusion 447 when the substrate W is inserted in the first slot 440 of the first supporting rod 440 and supported by the supporting unit 400. As treatment liquid flows through the first flow space 449, when a substrate W is treated in the second chemical liquid bath 142a, the treatment liquid such as a chemical can smoothly flow around the contact portion between the substrate W and the first slot 440.

Since a substrate W is supported by the top 447a of the contact protrusion 447 and treatment liquid flows to the first flow space 449 formed around the top 447a, there is an effect that the contact surface of the treatment liquid and a substrate W increases. In particular, when a substrate is treated with a high-temperature chemical, as treatment liquid flow to the first flow space 449, it is possible to minimize a temperature difference around the contact portion between the substrate and the supporting unit and it is possible to make the temperature distribution of the substrate uniform.

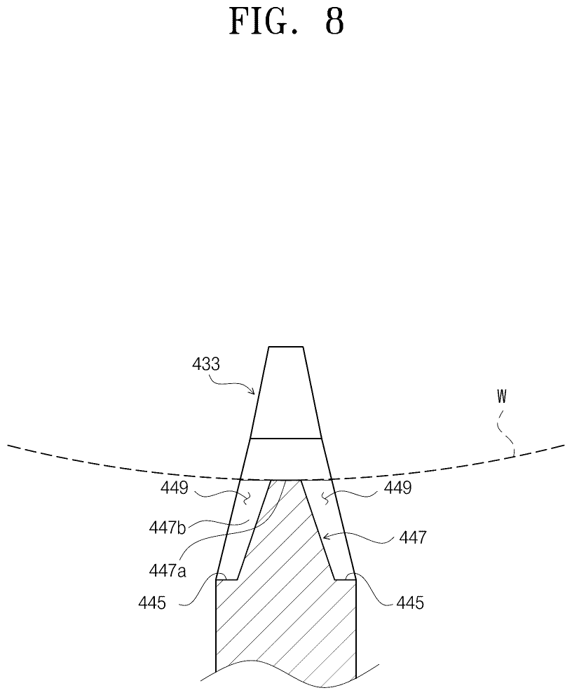

FIG. 8 is a view showing another embodiment of a contact protrusion formed on the bottom of the first slot. As in FIG. 8, a contact protrusion 447 may protrude from a partial region of the bottom 445 of the first slot 440. The first flow space 449 may be formed between a substrate W, the sides 447b of the supporting protrusion 447, the first regions 441a and 443a of the first side 441 and the second side 443, and the bottom 445.

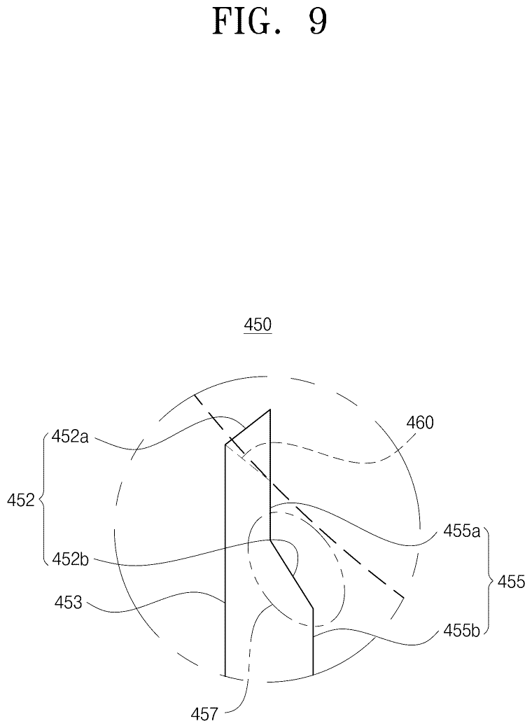

FIG. 9 is a detailed view showing the second supporting rod of FIG. 3 in a direction parallel with the longitudinal direction of the second supporting rod.

Hereafter, the second supporting rod 450 and the second slots 460 are described in detail with reference to FIG. 3 and FIG. 9.

The second supporting rod 450 includes a top 452, and outer side 453, and an inner side 455.

The top 452 may be composed of a first height portion 452a and a second height portion 452b. The first height portion 452a may be formed close to the outer side 453 of the second supporting rod 450 and the second height portion 452b may be formed close to the inner side 455 of the second supporting rod 450. As shown in FIG. 9, the first height portion 452a and the second height portion 452b each may be inclined. The first height portion 452a may be inclined to rise toward the inner side and the second height portion 452b may be inclined to rise toward the outer side.

The inner side 455 includes a first inner side 455a extending upward from the upper end of the second height portion 452a and a second inner side 455b extending downward from the lower end of the second height portion 452a. The first inner side 455a and the second inner side 455b are each perpendicular to the ground.

The distance between the outer side 453 and the inner side 455 of the second supporting rod 450 is defined as the thickness of the second supporting rod 450. The second supporting rod 450 has the same thickness at the portion lower than the second height portion 452b, but has a thickness at the portion higher than the second height portion 452b that is smaller than the thickness at the portion lower than the second height portion 452b. For example, as shown in FIG. 9, the sides 433 of the first supporting rod 430 may become thin as they go close to the top 431. That is, the thickness of the second supporting rod 450 at the point where the first inner side 455a is formed is smaller than the thickness of the second supporting rod 450 at the point where the inner side 455b is formed.

The second slot 46 formed at the second supporting rod 450 may be formed lower than the first height portion 452a. The second slot 460 may be formed between the first inner side 455a and the outer side 453. The front and rear of the second slot 460, that is, the directions of the first inner side 455a and the outer side 453 of the second supporting rod 450 are open toward the receiving space 316. The second slot 460 may be formed in a shape that can support a substrate W.

The second slot 460 is formed at a position higher than the second height portion 452b. That is, the lower end portion of the second slot 460 is positioned higher than the upper end of the second height portion 452b. Accordingly, as shown in FIG. 9, when a substrate W is inserted in the second slot 460, the second height portion 452b is spaced apart from the substrate W. A predetermined space is formed between a substrate W, the first inner side 455a, and the second height portion 452b. This is defined as a second flow space 457.

The second flow space 457 is positioned under the supporting surface that supports the end portion of a substrate W in contact with the end portion of the substrate W when the substrate W is inserted in the second slot 460 of the second supporting rod 460 and supported by the supporting unit 400. As treatment liquid flows through the second flow space 457, when a substrate W is treated in the second chemical liquid bath 142a, the treatment liquid such as a chemical can smoothly flow around the contact portion between the substrate W and the second slot 460.

Since a substrate W is supported by the second slot 460 formed between the outer side 453 and the first inner side 455a of the second supporting rod 450 and treatment liquid flows to the second flow space 457, the upper portion of the second height portion 452b does not come in contact with the substrate W, so there is an effect that the contact area between the treatment liquid and a substrate W increases. In particular, when a substrate is treated with a high-temperature chemical, as treatment liquid flow to the second flow space 457, it is possible to minimize a temperature difference around the contact portion between the substrate and the supporting unit and it is possible to make the temperature distribution of the substrate uniform.

Hereafter, an embodiment of a method for treating substrates W in the second batch treatment unit of FIG. 1 is described with reference to FIG. 1 to FIG. 2.

The second batch transfer unit 142c to which the supporting unit 400 supporting substrates W is coupled transfers substrates W to the second chemical liquid bath 142a.

The substrates W are loaded into the second chemical liquid bath 142a filled with a phosphoric acid solution and are immersed into the phosphoric acid solution in the inner bath 312 of the second chemical liquid bath 142a. The phosphoric acid solution is accommodated in a heated state in the second chemical liquid bath 142a.

The phosphoric acid solution in the second chemical liquid bath 142a circulates through the circulation line 330, whereby the substrates W are treated with the phosphoric acid solution.

The phosphoric acid solution supplied through the liquid supply pipe 331 from the inner bath 312 flows upward in the receiving space 316 and then overflows to the outer bath 314.

The phosphoric acid solution discharged through the discharge hole 338 of the outer bath 314 moves along the circulation line 330 and circulates at a set temperature through the pump 332, the filter 333, the valve 335, and the heater 337. While the phosphoric acid solution flows through the circulation line 330, foreign substances are removed by the filter 333 and the phosphoric acid solution keeps being heated to the set temperature.

When the treatment with the phosphoric acid solution is finished, the second batch transfer unit 142c to which the supporting unit 400 supporting a substrate W is coupled transfers the substrates W to the second rinse bath 142b with the inner bath 312 filled with the phosphoric acid solution.

Unlike, the phosphoric acid solution is drained through a drain hole 339 of the circulation line 330 and then the second batch transfer unit 142c may transfer the substrates W to the second rinse bath 142b.

The substrates W are loaded into the second rinse bath 142b filled with pure water by the second batch transfer unit 142c. The substrates W supported on the supporting unit 400 are immersed in this state into the pure water in the receiving space of the second ring bath 142b.

The pure water in the second ring bath 142b treats the substrates W.

After the treatment with the pure water is finished, the second transfer unit 134 can unload and transfer the substrates W to the posture changing bath 151 with the receiving space of the second ring bath 142b filled with pure water.

When the substrates W are transferred to the posture changing bath 151, spray liquid treatment may be additionally performed on the substrates W to maintain wetting of the substrates W.

The rinsed substrates W are moved to the posture changing unit 150 and are transferred to a standby chamber 210 in a horizontal posture by a single-type transfer robot 156 that changes the posture of substrates, and a single-type treating step can be additionally performed. In the single-type treating step, treatment can be performed on a single substrate W in a horizontal posture. The single-type treating step may include a liquid treating step of performing liquid treatment on substrates W in a single type and may include a drying step of drying substrates W in a single type. The liquid treating step can be performed in the liquid treatment chamber 230 when substrates W temporarily kept in the standby chamber 210 are transferred to the liquid treatment chamber 230. The drying step can be performed in the drying chamber 240 when the substrates W liquid-treated in the liquid treating step are transferred to the drying chamber 240. The substrates W that have undergone the single-type treating step are transferred to the buffer unit 250 and then can be transferred to the conveying container F placed in the second load port unit 270 by a second transfer robot 262 of a second transfer chamber 260, and a transfer device such as an OHT can hold and unload the conveying container F placed in the second load port unit 270 from the apparatus for treating a substrate. Detailed description of this process is omitted.

According to the embodiment described above, when substrates are treated in the treatment bath storing treatment liquid, the treatment liquid can smoothly flow around the contact portions between the substrates W and the supporting unit 400. Accordingly, it is possible to perform efficiently treat substrates.

A control unit 600 can control the apparatus 10 for treating a substrate. For example, the control unit 600 can control the components of the apparatus 10 for treating a substrate. For example, the control unit 600 can control the apparatus 10 for treating a substrate such that the apparatus 10 for treating a substrate can perform a process of treating substrates W.

For example, the control unit 600 can control at least one or more of the first load port unit 110, the index chamber 120, the transfer unit 130, the batch treatment unit 140, the posture changing unit 150, the buffer chamber 210, the first transfer chamber 220, the liquid treatment chamber 230, the drying chamber 240, and the second transfer chamber 260.

Further, the control unit 600 may include: a process controller that is a microprocessor (computer) that performs control of the apparatus 10 for treating a substrate; a user interface that is a keyboard through which an operator performs command input operation, etc. to manage the apparatus 10 for treating a substrate, a display that visualizes and displays the operation situation of the apparatus 10 for treating a substrate, etc. ; and a memory that stores a control program for performing treatment, which is performed in the apparatus 10 for treating a substrate, under control of the process controller, a program for performing treatment on each component in accordance with various data and treatment conditions, that is, a treatment recipe. Further, the user interface and the memory may be connected to the process controller. The processing recipe may be stored in a memory medium of the memory unit and the memory medium may be a hard disk and may be a portable disc such as a CD-ROM and a DVD, and a semiconductor memory such as a flash memory.

In the embodiment of the present disclosure, it was described that substrates W are treated in the second chemical liquid bath 142a as an embodiment. However, unlike this, substrates W may be treated in any one treatment bath selected from the second rinse bath 142b or the batch treatment baths 141a to 141b of the batch treatment unit 140.

In the embodiment described above, it was shown and described that one first supporting rod 430 is provided and two second supporting rods 450 are provided. However, unlike this, the number of the first supporting rod 430 and the second supporting rod 450 may be variously changed. For example, only any one of the first supporting rod 430 and the second supporting rod 450 may be provided in multiple quantities to support substrates W, and accordingly, the position where the end portion of a substrate W may also be changed.

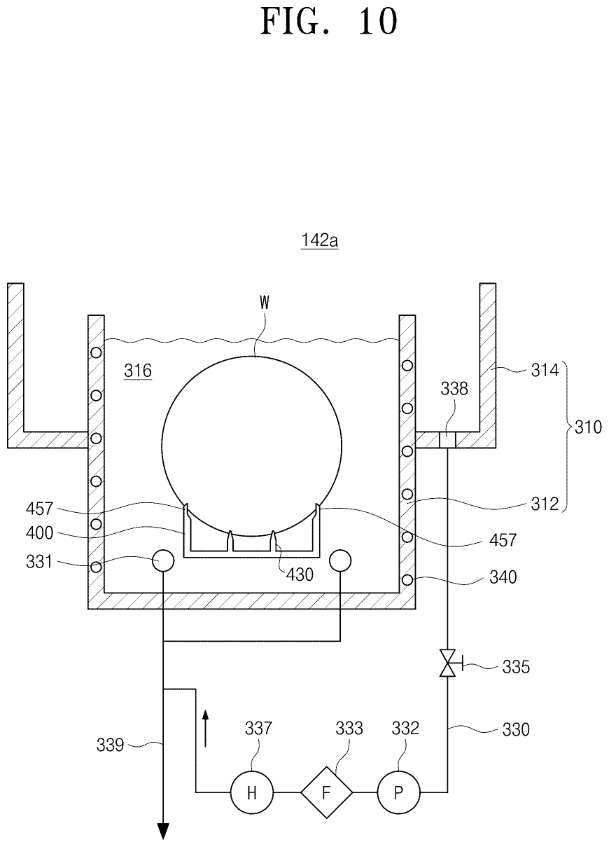

FIG. 10 shows the second chemical liquid bath of FIG. 1 in which a supporting unit according to another embodiment of the present invention is installed. As shown in FIG. 10, two first supporting rods 430 may be provided and configured to be able to support the end portion of a substrate W.

In the embodiment described above, it was described that the supporting unit 400 is coupled to the second batch transfer unit 142c to support substrates W. However, unlike this, the supporting unit 400 may be variously applied to supporting units that support substrates W in an apparatus of processing a substrate that immerses a plurality of substrates W in batch in a vertical posture in a treatment bath.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for treating a substrate, comprising:
a treatment bath having a receiving space accommodating treatment liquid, and treating a plurality of substrates; and
a supporting unit supporting the substrates in the treatment bath,
wherein the supporting unit includes:
a support having a first supporting rod supporting end portions of the substrates in a vertical state; and
a fixing plate coupled to the support and fixing the support,
a plurality of first slots in which edges of the substrates are inserted is formed at the first supporting rod,
each of the plurality of first slots is defined by a first side, a second side facing the first side, and a bottom,
a front and a rear of the first slot are open toward the receiving space, and
the bottom of the first slot comprises contact protrusions protruding upward from a lower end of the first side of the first slot and supporting lower end portions of the substrates.

2. The apparatus of claim 1, wherein the first side of the first slot and the second side of the first slot are provided such that a distance between the first side and the second side decreases downward.

3. The apparatus of claim 2, wherein the first side and the second side are inclined.

4. The apparatus of claim 2, wherein the first side and the second side of the first slot each have:
a first region extending upward from the bottom;
a second region extending upward from the first region; and
a third region extending upward from the second region,
the first region of the first side and the first region of the second side are disposed to face each other,
the second region of the first side and the second region of the second side are disposed to face each other,
the third region of the first side and the third region of the second side are disposed to face each other,
the second region of the first side and the second region of the second side are inclined surfaces, and
a distance between the second region of the first side and the second region of the second side is smaller than the third region of the first side and the third region of the second side.

5. The apparatus of claim 1, wherein the first side and the second side of the first slot are each provided such that a width of the surface increases downward.

6. The apparatus of claim 4, wherein the contact protrusion has a top, a first side, and a second side,
the top of the contact protrusion is a flat surface, and
the top of the contact protrusion supports a lower end portion of the substrate when the first supporting rod supports the substrate.

7. The apparatus of claim 6, wherein both sides of the contact protrusion are each inclined.

8. The apparatus of claim 6, wherein the top of the contact protrusion is provided at the same height as an upper end of the first region of the first side of the first slot.

9. The apparatus of claim 6, wherein a width of the top of the contact protrusion in a direction parallel with an arrangement direction of the first slots is the same as a thickness of the substrate.

10. The apparatus of claim 1, wherein the support further comprises a second supporting rod supporting end portions of the substrates in a vertical state, and
a plurality of second slots in which edges of the substrates are inserted is formed at the second supporting rod.

11. The apparatus of claim 10, wherein the second supporting rod comprises a top, a first side, and a second side,
the top of the second supporting rod comprises a first height portion and a second height portion lower than the first height portion,
the second slot is formed at the first height portion, and
the second slot is formed at a position higher than the second height portion.

12. The apparatus of claim 10, wherein a distance from a center of the substrate to the second supporting rod is larger than a distance from the center of the substrate to the first supporting rod when seen from above.

13. The apparatus of claim 1, further comprising a transfer robot coupled to an upper end of the fixing plate,
wherein the transfer robot immerses or unloads the supporting unit and the substrates supported on the supporting unit into or out of the treatment liquid by moving up or down the supporting unit.

14. An apparatus for treating a substrate, comprising:
a treatment bath having a receiving space accommodating treatment liquid, and treating a plurality of substrates; and
a supporting unit supporting the substrates in the treatment bath,
wherein the supporting unit comprises:
a support having a first supporting rod and a second supporting rod supporting end portions of the substrates in a vertical state; and
a fixing plate coupled to the support and fixing the support,
a plurality of first slots in which edges of the substrates are inserted is formed at the first supporting rod and a plurality of second slots in which edges of the substrates are inserted is formed at the second supporting rod,
the second supporting rod comprises a top, a first side, and a second side,
the top of the second supporting rod comprises a first height portion and a second height portion lower than the first height portion,
the second slot is formed at the first height portion, and
the second slot is formed at a position higher than the second height portion.

15. The apparatus of claim 14, wherein each of the plurality of first slots is defined by a first side, a second side facing the first side, and a bottom,
a front and a rear of the first slot are open toward the receiving space, and
the bottom of the first slot comprises contact protrusions protruding upward from a lower end of the first side of the first slot and supporting lower end portions of the substrates.

16. The apparatus of claim 15, wherein the first side of the first slot and the second side of the first slot are inclined such that a distance between the first side and the second side decreases downward.

17. The apparatus of claim 15, wherein the first side and the second side of the first slot each have:
a first region extending upward from the bottom;
a second region extending upward from the first region; and
a third region extending upward from the second region,
the first region of the first side and the first region of the second side are disposed to face each other,
the second region of the first side and the second region of the second side are disposed to face each other,
the third region of the first side and the third region of the second side are disposed to face each other,
the second region of the first side and the second region of the second side are inclined surfaces, and
a distance between the second region of the first side and the second region of the second side is smaller than the third region of the first side and the third region of the second side.

18. The apparatus of claim 17, wherein the contact protrusion has a top and sides,
the top of the contact protrusion is a flat surface, and
the top of the contact protrusion supports a lower end portion of the substrate when the first supporting rod supports the substrate.

19. The apparatus of claim 18, wherein the top of the contact protrusion is provided at the same height as an upper end of the first region of the first side of the first slot.

20. An apparatus for treating a substrate, comprising:
a treatment bath having a receiving space accommodating treatment liquid, and treating a plurality of substrates; and
a supporting unit supporting the substrates in the treatment bath,
wherein the supporting unit comprises:
a support having a first supporting rod and a second supporting rod supporting end portions of the substrates in a vertical state;
a fixing plate coupled to the support and fixing the support; and
a transfer robot coupled to an upper end of the fixing plate,
a plurality of first slots in which edges of the substrates are inserted is formed at the first supporting rod and a plurality of second slots in which edges of the substrates are inserted is formed at the second supporting rod,
each of the plurality of first slots is defined by a first side, a second side facing the first side, and a bottom,
a front and a rear of the first slot are open toward the receiving space, and
the bottom of the first slot comprises contact protrusions protruding upward from a lower end of the first side of the first slot and supporting lower end portions of the substrates,
the second supporting rod comprises a top, a first side, and a second side,
the top of the second supporting rod comprises a first height portion and a second height portion lower than the first height portion,
the second slot is formed at the first height portion,
the second slot is formed at a position higher than the second height portion, and
a distance from a center of the substrate to the second supporting rod is larger than a distance from the center of the substrate to the first supporting rod when seen from above.
